(19) United States
(12) Patent Application Publication
(10) Pub. No.: US 2026/0018456 A1
(43) Pub. Date: Jan. 15, 2026

(54) MANUFACTURING METHOD FOR SEMICONDUCTOR STRUCTURE

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/901,395

(22) Filed: Sep. 30, 2024

(30) Foreign Application Priority Data
Jul. 10, 2024 (CN) 202410924486.1

(51) Int. Cl. H01L 21/762

(52) U.S. Cl. CPC H01L 21/7624

(57) ABSTRACT

A manufacturing method for a semiconductor structure includes: providing a Si-supporting substrate having a SiO₂ protection layer on a surface of the Si-supporting substrate; thinning the SiO₂ protection layer to form a SiO₂ intermediate layer; disposing a Si growth substrate on a side, away from the Si-supporting substrate, of the SiO₂ intermediate layer; and disposing a device layer on a side, away from the Si-supporting substrate, of the Si growth substrate. The technical solutions of the present disclosure may reduce a possibility of generating parasitic capacitance and leakage current, and greatly improve the reliability of a device.

### CROSS-REFERENCE TO RELATED APPLICATIONS

The present application claims priority to Chinese Patent Application No. 202410924486.1, filed on Jul. 10, 2024, which is hereby incorporated by reference in its entirety.

### TECHNICAL FIELD

The present disclosure relates to the field of semiconductor technologies, and in particular, to a manufacturing method for a semiconductor structure.

### BACKGROUND

As a typical representation of the third generation of semiconductor materials, a wide band gap semiconductor material, such as a group III nitride material, has excellent characteristics, such as a large band gap width, a high voltage resistance, a high temperature resistance, a high electron saturation speed, a high electron drift speed, and easy formation of a high-quality heterojunction structure, which is very suitable for manufacturing high-temperature, high-frequency and high-power electronic devices.

The group III nitride material may be formed on a silicon substrate by an epitaxial growth process. In an actual product, Ga, Al or the like in the group III nitride material epitaxially grown on a silicon substrate is easy to diffuse into the silicon substrate, and form a p-type semiconductor conductive region in the silicon substrate, which may result in parasitic capacitance and leakage current, thereby greatly reducing the reliability of a device.

### SUMMARY

In view of this, embodiments of the present disclosure provide a manufacturing method for a semiconductor structure to solve a problem of parasitic capacitance and leakage current generated by a group III nitride device on a silicon substrate, so as to improve the reliability of the device.

According to an aspect of the present disclosure, an embodiment of the present disclosure provides a manufacturing method for a semiconductor structure, which includes: providing a Si-supporting substrate having a SiO₂ protection layer on a surface of the Si-supporting substrate; thinning the SiO₂ protection layer to form a SiO₂ intermediate layer; disposing a Si growth substrate on a side, away from the Si-supporting substrate, of the SiO₂ intermediate layer; and disposing a device layer on a side, away from the Si-supporting substrate, of the Si growth substrate.

As an optional embodiment, a thickness of the SiO₂ intermediate layer is less than 1 nm.

As an optional embodiment, the thickness of the SiO₂ intermediate layer is less than or equal to a thickness of a single atomic layer.

As an optional embodiment, the SiO₂ intermediate layer located at an interface of the Si growth substrate and the SiO₂ intermediate layer is discontinuous.

As an optional embodiment, a side, close to the device layer, of the SiO₂ intermediate layer includes a plurality of trenches partially penetrating the SiO₂ intermediate layer.

As an optional embodiment, the SiO₂ intermediate layer is discontinuous, and a side, close to the device layer, of the SiO₂ intermediate layer includes a plurality of trenches completely penetrating through the SiO₂ intermediate layer.

As an optional embodiment, at the interface of the Si growth substrate and the SiO₂ intermediate layer, a proportion of the SiO₂ intermediate layer on a unit area gradually increases, gradually decreases or periodically changes from a center to an edge.

As an optional embodiment, the Si growth substrate is n-type doping.

As an optional embodiment, an ion concentration of the n-type doping is less than or equal to 1E18 cm⁻³.

As an optional embodiment, an ion concentration of the n-type doping of the Si growth substrate decreases in a direction close to the device layer.

As an optional embodiment, the device layer includes at least one element, each element of the at least one element at least diffuses into the Si growth substrate to form a plurality of p-type doped regions, and a thickness of each p-type doped region of the plurality of p-type doped regions is less than a sum of thicknesses of the Si growth substrate, the SiO₂ intermediate layer and the Si-supporting substrate.

As an optional embodiment, in a direction pointing from the Si growth substrate to the Si-supporting substrate, a width of the p-type doped region decreases.

As an optional embodiment, at an interface of the Si growth substrate and the SiO₂ intermediate layer, the width of the p-type doped region is decreased in a hopping manner.

As an optional embodiment, in the direction pointing from the Si growth substrate to the Si-supporting substrate, a width reduction speed of the p-type doped region in the SiO₂ intermediate layer is greater than a width reduction speed of the p-type doped region in the Si growth substrate and a width reduction speed of the p-type doped region in the Si-supporting substrate.

As an optional embodiment, in a direction pointing from the Si growth substrate to the Si-supporting substrate, an element doping concentration of the p-type doped region decreases.

As an optional embodiment, in the direction pointing from the Si growth substrate to the Si-supporting substrate, an element doping concentration reduction speed of the p-type doped region in the SiO₂ intermediate layer is greater than an element doping concentration reduction speed of the p-type doped region in the Si growth substrate and an element doping concentration reduction speed of the p-type doped region in the Si-supporting substrate.

As an optional embodiment, a width of at least one p-type doped region of the plurality of p-type doped regions is different from widths of remaining p-type doped regions of the plurality of p-type doped regions.

As an optional embodiment, a thickness of at least one p-type doped region of the plurality of p-type doped regions is different from thicknesses of remaining p-type doped regions of the plurality of p-type doped regions.

As an optional embodiment, the element includes B element, Ga element, Al element, Mg element, In element or Zn element.

As an optional embodiment, an element doping concentration of the p-type doped region is less than or equal to 1E18 cm⁻³.

### BRIEF DESCRIPTION OF THE DRAWINGS

FIG. 1 is a flowchart of a manufacturing method for a semiconductor structure according to an embodiment of the present disclosure.

FIG. 2 to FIG. 5 are schematic structural diagrams of intermediate structures in a process of manufacturing a semiconductor structure according to an embodiment of the present disclosure.

FIG. 6 to FIG. 7 are schematic structural diagrams of semiconductor structures according to some embodiments of the present disclosure.

FIG. 8 to FIG. 10 are schematic structural diagrams of semiconductor structures according to some embodiments of the present disclosure.

FIG. 11 is a schematic structural diagram of a semiconductor structure according to an embodiment of the present disclosure.

FIG. 12 to FIG. 13 are schematic structural diagrams of semiconductor structures according to some embodiments of the present disclosure.

FIG. 14 is a schematic structural diagram of a semiconductor structure according to an embodiment of the present disclosure.

### DETAILED DESCRIPTION OF THE EMBODIMENTS

Technical solutions in embodiments of the present disclosure are described clearly and completely below with reference to the accompanying drawings of the embodiments of the present disclosure. Apparently, the described embodiments are only a part, but not all of the embodiments of the present disclosure. All other embodiments that may be obtained by those of ordinary skill in the art based on the embodiments in the present disclosure without any inventive efforts fall into the protection scope of the present disclosure.

In order to solve a problem of parasitic capacitance and leakage current generated by a group III nitride device on a silicon substrate to improve the reliability of the device, the present disclosure provides a manufacturing method for a semiconductor structure. The manufacturing method may include: providing a Si-supporting substrate having a SiO₂ protection layer on a surface of the Si-supporting substrate; thinning the SiO₂ protection layer to form a SiO₂ intermediate layer; disposing a Si growth substrate on a side, away from the Si-supporting substrate, of the SiO₂ intermediate layer; and disposing a device layer on a side, away from the Si-supporting substrate, of the Si growth substrate. The SiO₂ intermediate layer provided in the present disclosure may effectively reduce the diffusion of an element such as Ga/Al in a group III-V material device layer to the substrate, thereby reducing a possibility of generating parasitic capacitance and leakage current, and greatly improving the reliability of the device. An n-type doped Si growth substrate provided in the present disclosure may further perform compensation doping on a diffused element such as Ga/Al, to further avoid parasitic capacitance and leakage current.

A manufacturing method for a semiconductor structure mentioned in the present disclosure is further illustrated with examples below with reference to FIG. 1 to FIG. 14.

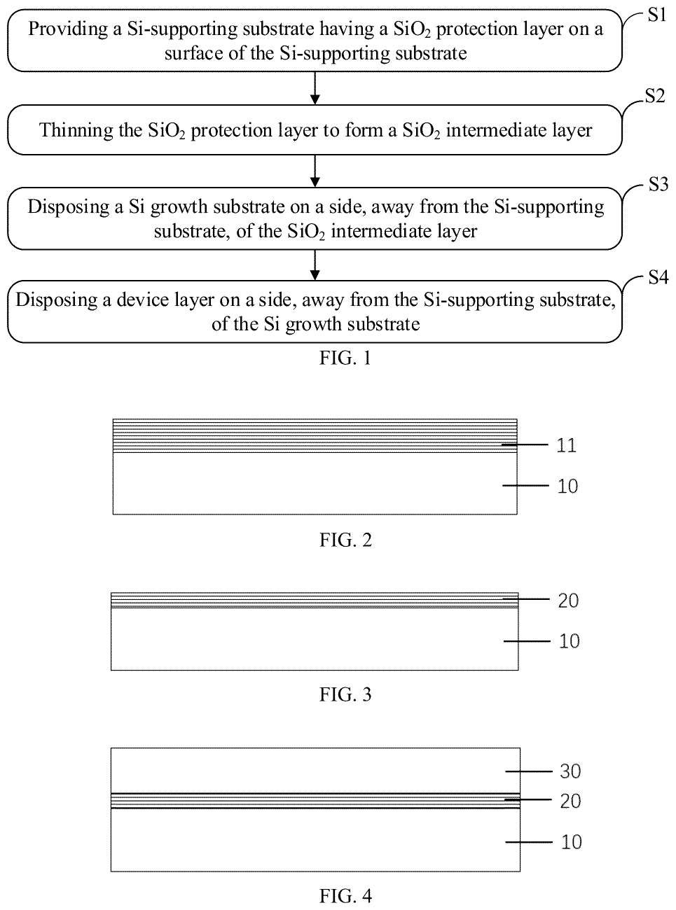

FIG. 1 is a flowchart of a manufacturing method for a semiconductor structure according to an embodiment of the present disclosure, and FIG. 2 to FIG. 5 are schematic structural diagrams of intermediate structures in a process of manufacturing a semiconductor structure according to an embodiment of the present disclosure. As shown in FIG. 1, the manufacturing method for the semiconductor structure provided by an embodiment of the present disclosure may include the following steps.

S1: providing a Si-supporting substrate having a SiO₂ protection layer on a surface of the Si-supporting substrate.

Specifically, as shown in FIG. 2, the Si-supporting substrate 10 having the SiO₂ protection layer 11 on the surface of the Si-supporting substrate 10 is provided. The substrate may be a commercially available Si substrate, and a surface of the Si substrate is provided with a SiO₂ layer, which may protect the surface of the Si substrate and avoid defects such as scratches caused in a transportation process. Generally, the commercially available Si substrate needs to remove the SiO₂ layer from the surface of the Si substrate before use, but the SiO₂ layer on the surface of the commercially available Si substrate is not completely removed in the embodiment.

S2: thinning the SiO₂ protection layer to form a SiO₂ intermediate layer.

Specifically, as shown in FIG. 3, the SiO₂ protection layer 11 is thinned to form the SiO₂ intermediate layer 20. In this embodiment, the SiO₂ protection layer 11 is thinned and a part of the SiO₂ protection layer 11 is retained to form the SiO₂ intermediate layer 20, rather than completely removing the SiO₂ layer on the surface of the commercially available Si substrate. By providing the SiO₂ intermediate layer 20, a possibility of parasitic capacitance and leakage current generated by a nitride device on the Si substrate may be reduced. A thickness of the SiO₂ intermediate layer 20 may be less than 1 nm. Optionally, the thickness of the SiO₂ intermediate layer 20 is less than or equal to a thickness of a single atomic layer.

S3: disposing a Si growth substrate on a side, away from the Si-supporting substrate, of the SiO₂ intermediate layer.

Specifically, as shown in FIG. 4, the Si growth substrate 30 is disposed on the side, away from the Si-supporting substrate 10, of the SiO₂ intermediate layer 20. Optionally, the Si growth substrate 30 is n-type doping, and an ion concentration of the n-type doping is less than or equal to 1E18 cm⁻³. The ion concentration of the n-type doping of the Si growth substrate 30 decreases in a direction close to a subsequently prepared device layer 40.

S4: disposing a device layer on a side, away from the Si-supporting substrate, of the Si growth substrate.

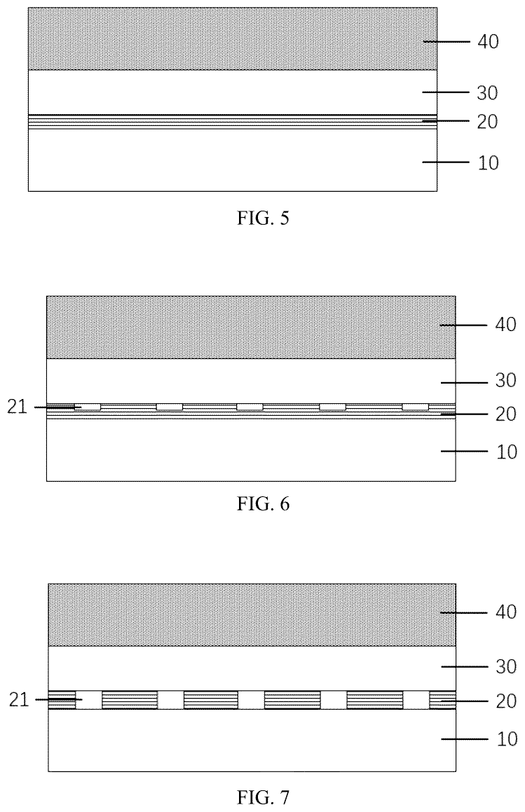

Specifically, as shown in FIG. 5, the device layer 40 is disposed on the side, away from the Si-supporting substrate 10, of the Si growth substrate 30. A material of the device layer 40 includes a group III nitride material.

In an embodiment, FIG. 6 to FIG. 7 are schematic structural diagrams of semiconductor structures according to some embodiments of the present disclosure. As shown in FIG. 5, the SiO₂ intermediate layer 20 of the semiconductor structure is a continuous film layer entirely covering a surface of the Si-supporting substrate 10, and a surface of a side, away from the Si-supporting substrate 10, of the SiO₂ intermediate layer 20 is a plane. Optionally, the SiO₂ intermediate layer 20 located at an interface of the Si growth substrate 30 and the SiO₂ intermediate layer 20 is discontinuous. As shown in FIG. 6, a side, close to the device layer 40, of the SiO₂ intermediate layer 20 includes a plurality of trenches 21 partially penetrating the SiO₂ intermediate layer 20, or, as shown in FIG. 7, the SiO₂ intermediate layer 20 is discontinuous, and a side, close to the device layer 40, of the SiO₂ intermediate layer 20 includes a plurality of trenches 21 completely penetrating through the SiO₂ intermediate layer 20. The trenches 21 disposed in the SiO₂ intermediate layer 20 may further block diffusion paths of an element such as Ga/Al in the group III-V material device layer to the substrate, thereby reducing a possibility of generating parasitic capacitance and leakage current, and greatly improving the reliability of the device. At the same time, the trenches 21 may attenuate a stress transmitted from the device layer 40 to the substrate, so as to improve a mechanical strength of the substrate and avoid deformation in a subsequent epitaxy process. Optionally, at the interface of the Si growth substrate 30 and the SiO₂ intermediate layer 20, a proportion of the SiO₂ intermediate layer 20 on a unit area gradually increases, gradually decreases, or periodically changes from a center to an edge, which may change a size and distribution of the trenches 21, thereby changing the proportion of the SiO₂ intermediate layer 20 on a unit area at the interface of the growth substrate 30 and the SiO₂ intermediate layer 20, further achieving a uniform diffusion barrier effect and making a stress distribution more uniform.

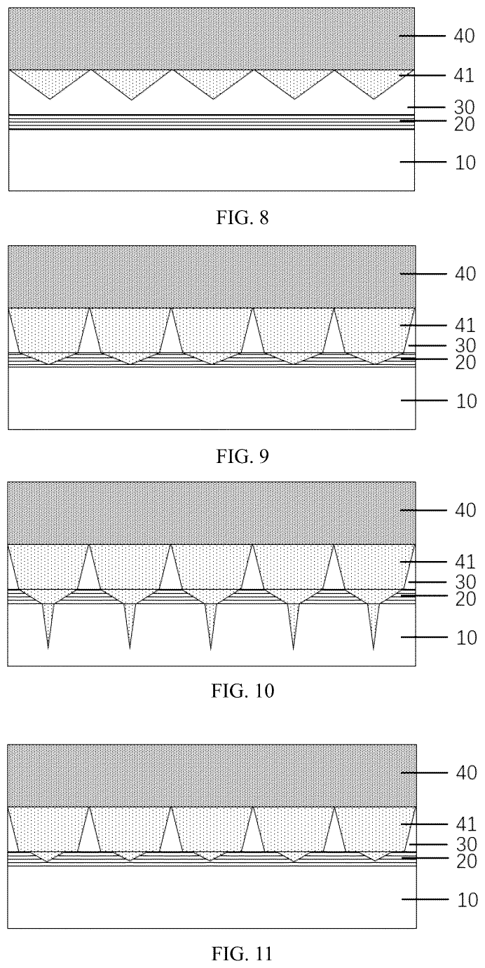

In an embodiment, FIG. 8 to FIG. 10 are schematic structural diagrams of semiconductor structures according to some embodiments of the present disclosure. A device layer 40 includes at least one element, the element at least diffuses into the Si growth substrate 30 to form a plurality of p-type doped regions 41, and a thicknesses of the p-type doped region 41 is less than a sum of thicknesses of the Si growth substrate 30, the SiO₂ intermediate layer 20 and the Si-supporting substrate 10. Optionally, as shown in FIG. 8, an element of the device layer 40 merely diffuses into the Si growth substrate 30, and the p-type doped region 41 is located in the Si growth substrate 30. As shown in FIG. 9, an element of the device layer 40 diffuses into the Si growth substrate 30 and the SiO₂ intermediate layer 20, and the p-type doped region 41 is located in the Si growth substrate 30 and the SiO₂ intermediate layer 20. As shown in FIG. 10, an element of the device layer 40 diffuses into the Si growth substrate 30, the SiO₂ intermediate layer 20 and the Si-supporting substrate 10, and the p-type doped region 41 is located in the Si growth substrate 30, the SiO₂ intermediate layer 20 and the Si-supporting substrate 10. An element diffusion depth of the device layer 40 may be affected by conditions such as element concentration. An element doping concentration of the p-type doped region 41 is less than or equal to 1E18 cm⁻³. A diffusion element of the device layer 40 includes B element, Ga element, Al element, Mg element, In element or Zn element.

In an embodiment, as shown in FIG. 10, in a direction pointing from the Si growth substrate 30 to the Si-supporting substrate 10, a width of the p-type doped region 41 decreases. Moreover, in a direction pointing from the Si growth substrate 30 to the Si-supporting substrate 10, a width reduction speed of the p-type doped region 41 in the SiO₂ intermediate layer 20 is greater than a width reduction speed of the p-type doped region 41 in the Si growth substrate 30 and a width reduction speed of the p-type doped region 41 in the Si-supporting substrate 10.

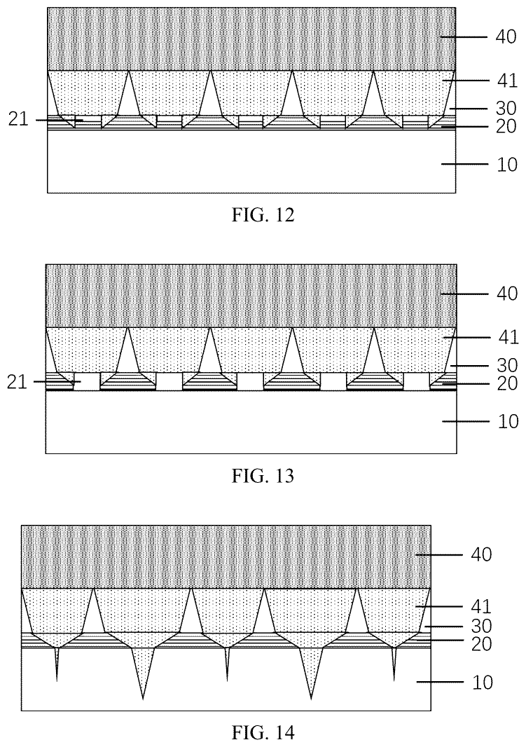

In an embodiment, FIG. 11 is a schematic structural diagram of a semiconductor structure according to an embodiment of the present disclosure. As shown in FIG. 11, at an interface of the Si growth substrate 30 and the SiO₂ intermediate layer 20, a width of the p-type doped region 41 is decreased in a hopping manner. Optionally, at an interface of the SiO₂ intermediate layer 20 and the Si-supporting substrate 10, a width of the p-type doped region 41 is decreased in a hopping manner. The SiO₂ intermediate layer 20 may effectively prevent element diffusion and reduce a depth of the p-type doped region 41.

In an embodiment, in a direction pointing from the Si growth substrate 30 to the Si-supporting substrate 10, an element doping concentration of the p-type doped region 41 decreases. Moreover, in the direction pointing from the Si growth substrate 30 to the Si-supporting substrate 10, an element doping concentration reduction speed of the p-type doped region 41 in the SiO₂ intermediate layer is greater than an element doping concentration reduction speed of the p-type doped region 41 in the Si growth substrate 30 and an element doping concentration reduction speed of the p-type doped region 41 in the Si-supporting substrate 10. By providing the SiO₂ intermediate layer 20, a diffusion of an element in the device layer 40 may be significantly inhibited. At the same time, the n-type doping in the Si growth substrate 30 may further perform compensation doping on the element diffused into the substrate, so as to improve a resistivity of the substrate and avoid parasitic capacitance and leakage current. Optionally, in a direction pointing from the Si growth substrate 30 to the Si-supporting substrate 10, a width and an element doping concentration of the p-type doped region 41 both gradually decrease. Moreover, in the direction pointing from the Si growth substrate 30 to the Si-supporting substrate 10, a width reduction speed and an element doping concentration reduction speed of the p-type doped region 41 in the SiO₂ intermediate layer 20 are greater than a width reduction speed and an element doping concentration reduction speed of the p-type doped region 41 in the Si growth substrate 30 and a width reduction speed and an element doping concentration reduction speed of the p-type doped region 41 in the Si-supporting substrate 10.

In an embodiment, FIG. 12 to FIG. 13 are schematic structural diagrams of semiconductor structures according to some embodiments of the present disclosure. The SiO₂ intermediate layer 20 at an interface of the Si growth substrate 30 and the SiO₂ intermediate layer 20 is discontinuous, and a side, close to the device layer 40, of the SiO₂ intermediate layer 20 includes a plurality of trenches 21 at least partially penetrating the SiO₂ intermediate layer 20. Optionally, as shown in FIG. 12, a side, close to the device layer 40, of the SiO₂ intermediate layer 20 includes a plurality of trenches 21 partially penetrating the SiO₂ intermediate layer 20. Optionally, as shown in FIG. 13, the SiO₂ intermediate layer 20 is discontinuous, and a side, close to the device layer 40, of the SiO₂ intermediate layer 20 includes a plurality of trenches 21 completely penetrating through the SiO₂ intermediate layer 20. An element of the device layer 40 form a p-type doped region 41 in the Si growth substrate 30 and the SiO₂ intermediate layer 20, and the p-type doped region 41 in the SiO₂ intermediate layer 20 is located between trenches 21 (as shown in FIG. 12 and FIG. 13). The trenches 21 provided in the SiO₂ intermediate layer 20 may effectively block a diffusion path of the element in the device layer 40, and further inhibit the diffusion of the element in the device layer 40, thereby further avoiding parasitic capacitance and leakage current. At the same time, the trenches 21 may attenuate a stress transmitted from the device layer 40 to the substrate, so as to improve a mechanical strength of the substrate and avoid deformation in a subsequent epitaxy process. Optionally, at an interface of the Si growth substrate 30 and the SiO₂ intermediate layer 20, a proportion of the SiO₂ intermediate layer 20 on a unit area gradually increases, gradually decreases, or periodically changes from a center to an edge, which may change a size and distribution of the trenches 21, thereby changing the proportion of the SiO₂ intermediate layer 20 on a unit area at the interface of the growth substrate 30 and the SiO₂ intermediate layer 20, further achieving a uniform diffusion barrier effect and making a stress distribution more uniform.

In an embodiment, FIG. 14 is a schematic structural diagram of a semiconductor structure according to an embodiment of the present disclosure. Due to the fact that the device layer 40 is not perfectly uniform in an epitaxy process, there may be local defects, and different crystal regions may be formed in the epitaxy process. Different epitaxial crystal regions have different diffusion capabilities, and an element distribution in the device layer 40 is not completely uniform, which may result in that widths or thicknesses of a plurality of the p-type doped regions 41 formed by element diffusion through an interface of the device layer 40 and the growth substrate 30 are not exactly the same. As shown in FIG. 14, a width of at least one p-type doped region 41 is different from a width of another p-type doped region 41, and/or a thickness of at least one p-type doped region 41 is different from a thickness of another p-type doped region 41.

The present disclosure provides a manufacturing method for a semiconductor structure, in an embodiment of the present disclosure, a Si-supporting substrate having a SiO₂ protection layer on a surface of the Si-supporting substrate is provided, the SiO₂ protection layer is thinned to form a SiO₂ intermediate layer, a Si growth substrate is disposed on a side, away from the Si-supporting substrate, of the SiO₂ intermediate layer, and a device layer is disposed on a side, away from the Si-supporting substrate, of the Si growth substrate. The SiO₂ intermediate layer provided in the present disclosure may effectively reduce the diffusion of an element such as Ga/Al in a group III-V material device layer to the substrate, thereby reducing a possibility of generating parasitic capacitance and leakage current, and greatly improving the reliability of the device. An n-type doped Si growth substrate provided in the present disclosure may further perform compensation doping on a diffused element such as Ga/Al, to further avoid parasitic capacitance and leakage current.

It should be understood that the terms “including” and its modification used in this disclosure are open-ended, that is, “including but not limited to”. The term “an embodiment” represents “at least one embodiment”; and the term “another embodiment” means “at least one another embodiment”. In this specification, a schematic description of foregoing terms does not have to be directed to a same embodiment or example. Furthermore, specific features, structures, materials, or characteristics described may be incorporated in an appropriate manner in any one or more embodiments or examples. In addition, without being contradictory, a person skilled in the art may combine and permutate different embodiments or examples described in this specification and features of different embodiments or examples.

The foregoing descriptions are merely exemplary embodiments of the present disclosure, but are not intended to limit the present disclosure. Any modification, an equivalent replacement, or the like made within a spirit and principles of the present disclosure shall be included in a protection scope of the present disclosure.

What is claimed is:

1. A manufacturing method for a semiconductor structure, comprising:
providing a Si-supporting substrate having a SiO₂ protection layer on a surface of the Si-supporting substrate;
thinning the SiO₂ protection layer to form a SiO₂ intermediate layer;
disposing a Si growth substrate on a side, away from the Si-supporting substrate, of the SiO₂ intermediate layer; and
disposing a device layer on a side, away from the Si-supporting substrate, of the Si growth substrate.

2. The manufacturing method for the semiconductor structure according to claim 1, wherein a thickness of the SiO₂ intermediate layer is less than 1 nm.

3. The manufacturing method for the semiconductor structure according to claim 2, wherein the thickness of the SiO₂ intermediate layer is less than or equal to a thickness of a single atomic layer.

4. The manufacturing method for the semiconductor structure according to claim 1, wherein the SiO₂ intermediate layer located at an interface of the Si growth substrate and the SiO₂ intermediate layer is discontinuous.

5. The manufacturing method for the semiconductor structure according to claim 4, wherein a side, close to the device layer, of the SiO₂ intermediate layer comprises a plurality of trenches partially penetrating the SiO₂ intermediate layer.

6. The manufacturing method for the semiconductor structure according to claim 4, wherein the SiO₂ intermediate layer is discontinuous, and a side, close to the device layer, of the SiO₂ intermediate layer comprises a plurality of trenches completely penetrating through the SiO₂ intermediate layer.

7. The manufacturing method for the semiconductor structure according to claim 4, wherein at the interface of the Si growth substrate and the SiO₂ intermediate layer, a proportion of the SiO₂ intermediate layer on a unit area gradually increases, gradually decreases or periodically changes from a center to an edge.

8. The manufacturing method for the semiconductor structure according to claim 1, wherein the Si growth substrate is n-type doping.

9. The manufacturing method for the semiconductor structure according to claim 8, wherein an ion concentration of the n-type doping is less than or equal to 1E18 cm⁻³.

10. The manufacturing method for the semiconductor structure according to claim 8, wherein an ion concentration of the n-type doping of the Si growth substrate decreases in a direction close to the device layer.

11. The manufacturing method for the semiconductor structure according to claim 1, wherein the device layer comprises at least one element, each element of the at least one element at least diffuses into the Si growth substrate to form a plurality of p-type doped regions, and a thickness of each p-type doped region of the plurality of p-type doped regions is less than a sum of thicknesses of the Si growth substrate, the SiO₂ intermediate layer and the Si-supporting substrate.

12. The manufacturing method for the semiconductor structure according to claim 11, wherein in a direction pointing from the Si growth substrate to the Si-supporting substrate, a width of the p-type doped region decreases.

13. The manufacturing method for the semiconductor structure according to claim 12, wherein at an interface of the Si growth substrate and the SiO₂ intermediate layer, the width of the p-type doped region is decreased in a hopping manner.

14. The manufacturing method for the semiconductor structure according to claim 12, wherein in the direction pointing from the Si growth substrate to the Si-supporting substrate, a width reduction speed of the p-type doped region in the SiO₂ intermediate layer is greater than a width reduction speed of the p-type doped region in the Si growth substrate and a width reduction speed of the p-type doped region in the Si-supporting substrate.

15. The manufacturing method for the semiconductor structure according to claim 11, wherein in a direction pointing from the Si growth substrate to the Si-supporting substrate, an element doping concentration of the p-type doped region decreases.

16. The manufacturing method for the semiconductor structure according to claim 15, wherein in the direction pointing from the Si growth substrate to the Si-supporting substrate, an element doping concentration reduction speed of the p-type doped region in the SiO₂ intermediate layer is greater than an element doping concentration reduction speed of the p-type doped region in the Si growth substrate and an element doping concentration reduction speed of the p-type doped region in the Si-supporting substrate.

17. The manufacturing method for the semiconductor structure according to claim 11, wherein a width of at least one p-type doped region of the plurality of p-type doped regions is different from widths of remaining p-type doped regions of the plurality of p-type doped regions.

18. The manufacturing method for the semiconductor structure according to claim 11, wherein a thickness of at least one p-type doped region of the plurality of p-type doped regions is different from thicknesses of remaining p-type doped regions of the plurality of p-type doped regions.

19. The manufacturing method for the semiconductor structure according to claim 11, wherein the element comprises B element, Ga element, Al element, Mg element, In element or Zn element.

20. The manufacturing method for the semiconductor structure according to claim 11, wherein an element doping concentration of the p-type doped region is less than or equal to 1E18 cm⁻³.
